(19) United States
(12) Patent Application Publication
(10) Pub. No.: US 2024/0379613 A1
(43) Pub. Date: Nov. 14, 2024

(54) PIN WIRE FORMING METHOD, WIRE BONDING APPARATUS, AND BONDING TOOL

(71) Applicant: SHINKAWA LTD., Tokyo (JP)

(72) Inventors: Hiroshi MUNAKATA, Tokyo (JP); Toshihiko TOYAMA, Tokyo (JP)

(73) Assignee: SHINKAWA LTD., Tokyo (JP)

(21) Appl. No.: 18/692,326

(22) PCT Filed: Sep. 16, 2021
(86) PCT No.: PCT/JP2021/034083

§ 371 Date: Mar. 14, 2024

(51) Int. Cl. H01L 23/00

(52) U.S. Cl. CPC H01L 24/78; H01L 24/745; H01L 24/85; H01L 2224/745; H01L 2224/78303; H01L 2224/78353; H01L 2224/7865; H01L 2224/78821; H01L 2224/85091; H01L 2224/85205; H01L 2924/1431

(57) ABSTRACT

The present invention includes a bonding process of bonding a wire to an electrode by a capillary, a wire feeding process of raising the capillary to feed the wire from a tip, a pressing process of moving the capillary to press an inner edge of the capillary against the wire, a scraping process of vibrating the tip of the capillary to form a scrape on a side surface of the wire by the inner edge of the capillary, and a cut-off process of closing a wire clamper and cutting off the wire at a portion of the scrape to form a pin wire extending vertically upward from the electrode.

### TECHNICAL FIELD

The present invention relates to a method of forming a pin wire that extends vertically upward from a bonding position by a wire bonding apparatus, and a structure of a wire bonding apparatus and a structure of a bonding tool used in the wire bonding apparatus.

In a wire bonding apparatus, after ultrasonically vibrating a bonding tool with a wire being pressed onto an electrode by the bonding tool to bond the wire and the electrode, the wire is passed to a lead, and with the passed wire being pressed onto the lead, the bonding tool is ultrasonically vibrated to bond the wire and the lead.

In the wire bonding apparatus, a method of vibrating the tip of the bonding tool in multiple directions has been proposed to improve the bonding quality and the bonding strength (e.g., see Patent Document 1).

On the other hand, there is a need to form, on an electrode of a semiconductor chip or a substrate, a pin wire extending vertically upward from the electrode. Thus, the following method has been proposed. After bonding a wire to a bonding position of a semiconductor chip or a substrate using a bonding tool by a wire bonding apparatus, the wire is extended to another position on the semiconductor chip or the substrate, a portion of the wire is pressed at the another position, and afterwards, after moving the bonding tool so that the wire is vertically upward from the electrode, the wire is cut off to form a pin wire (e.g., see Patent Document 2).

### RELATED ART DOCUMENTS

### Patent Documents

Patent Document 1: Japanese Patent No. 6180736

Patent Document 2: Japanese Patent No. 6297553

### SUMMARY OF INVENTION

### Problems to Be Solved by Invention

When forming a pin wire on an electrode of a semiconductor chip using the related art described in Patent Document 2, it is required to press a portion of the wire at another location on the semiconductor chip or the substrate. However, depending on the height of the pin wire, there may be no space for pressing the wire, which makes it difficult to form the pin wire. Further, in the case where the pitch of the pin wires is narrow, when pressing a portion of the wire, it may interfere with an adjacent pin wire.

Thus, it is an objective of the present invention to form a pin wire without pressing a portion of the wire at a location different from a bonding position.

### Means for Solving Problems

A pin wire forming method according to the present invention includes a bonding process, a wire feeding process, a pressing process, a scraping process, and a cut-off process. In the bonding process, a wire is bonded to a bonding position by a bonding tool. In the wire feeding process, the bonding tool is raised and the wire is fed from a tip of the bonding tool so that the wire extends upward from the bonding position. In the pressing process, the bonding tool is moved to press an inner edge of the bonding tool against the wire. In the scraping process, the tip of the bonding tool is vibrated to form a scrape on the wire by the inner edge of the bonding tool. In the cut-off process, the bonding tool is raised and a wire clamper is closed to cut off the wire at a portion of the scrape and form a pin wire extending upward from the bonding position.

Thus, by vibrating the bonding tool with the inner edge of the bonding tool being in contact with the wire, a scrape can be formed on the wire, and when the wire clamper is closed to cut off the wire, the wire can be cut off at the scrape to form a pin wire.

In the pin wire forming method according to the present invention, the pressing process may incline the wire by moving the tip of the bonding tool obliquely downward to press the inner edge of the bonding tool against a side surface of the wire. The scraping process may vibrate the tip of the bonding tool with the wire being inclined to form the scrape on the wire by the inner edge of the bonding tool. The pin wire forming method may include a wire standing process of moving the tip of the bonding tool obliquely upward to above the bonding position to stand the wire to extend vertically upward from the bonding position.

Thus, during the pressing process, since the wire is inclined and the tip of the bonding tool is vibrated with the inner edge of the bonding tool being in contact with the side surface of the wire, a deep scrape can be formed on the side surface of the wire, and when the wire clamper is closed to cut off the wire, the wire can be reliably cut off at the scrape to form a pin wire. Further, since the inclined wire is stood up and then cut off, the pin wire can be formed in a shape extending vertically upward from the bonding position.

In the pin wire forming method according to the present invention, the scraping process may vibrate the tip of the bonding tool in any one or more directions among an X direction, a Y direction, and a Z direction by ultrasonically vibrating the bonding tool.

Thus, by ultrasonically vibrating the bonding tool to ultrasonically vibrate the tip of the bonding tool, a scrape can be effectively formed on the side surface of the wire by high-frequency friction between the inner edge of the bonding tool and the side surface of the wire.

In the pin wire forming method according to the present invention, the scraping process may vibrate the tip of the bonding tool in any one or more directions among an X direction, a Y direction, and a Z direction by a moving mechanism which moves the tip of the bonding tool in the X direction, the Y direction, and the Z direction.

Thus, by vibrating the tip of the bonding tool in the XYZ directions, a larger scrape can be formed.

In the pin wire forming method according to the present invention, the moving mechanism may be composed of a Z-direction motor that drives a bonding arm to which the bonding tool is attached at a front end to move the tip of the bonding tool in the Z direction, and an XY table which moves a bonding head attached with the bonding arm in XY directions.

Since the tip of the bonding tool is vibrated in the XYZ directions using the Z-direction motor and the XY table which are generally equipped in a bonding apparatus, the tip of the bonding tool can be vibrated in the XYZ directions without a special device for vibrating the tip of the bonding tool in the XYZ directions.

In the pin wire forming method according to the present invention, the bonding tool may include a tip surface, a recess, and a through-hole. The recess is recessed from the tip surface toward a root and narrows toward the root. The through-hole is connected to a bottom surface of the recess and extends toward the root, and the wire is inserted through the through-hole. The inner edge may be a corner part at which the bottom surface of the recess and an inner surface of the through-hole are connected.

Thus, since the corner part is brought into contact with the side surface of the wire, when the tip of the bonding tool is vibrated, the side surface of the wire can be scraped by the corner part to locally form a deep scrape on the side surface of the wire.

In the pin wire forming method according to the present invention, the bottom surface of the recess of the bonding tool may be inclined so that an outer peripheral side is recessed to a root side. An internal angle of the corner part of the bonding tool may be 90° or less.

Thus, the inner edge can dig into the side surface of the wire with less force, and a deep scrape can be formed.

In the pin wire forming method according to the present invention, the through-hole of the bonding tool may have a tapered shape having a diameter that increases toward a root side. An internal angle of the corner part of the bonding tool may be 90° or less.

Thus, the inner edge can dig into the side surface of the wire with less force, and a deep scrape can be formed.

In the pin wire forming method according to the present invention, the recess of the bonding tool may have an inclined surface which is inclined with respect to a center line of the bonding tool at the tip surface. The pressing process may incline the wire to an inclination angle of the inclined surface of the recess by moving the tip of the bonding tool obliquely downward to press the inner edge of the bonding tool against a side surface of the wire.

Thus, the inner edge can be reliably brought into contact with the side surface of the wire to form a scrape on the side surface of the wire.

A wire bonding apparatus according to the present invention is a wire bonding apparatus which bonds a wire to a bonding position and includes a bonding tool, an ultrasonic transducer, a moving mechanism, a wire clamper, and a control part. The ultrasonic transducer ultrasonically vibrates the bonding tool. The moving mechanism moves the bonding tool. The wire clamper grips the wire. The control part adjusts operations of the ultrasonic transducer, the moving mechanism, and the wire clamper. The control part is configured to: lower a tip of the bonding tool to the bonding position by the moving mechanism to bond the wire to the bonding position by the bonding tool, raise the bonding tool by the moving mechanism to feed the wire from the tip so that the wire extends upward from the bonding position, move the bonding tool by the moving mechanism to press an inner edge of the bonding tool against the wire, vibrate the tip of the bonding tool by one or both of the ultrasonic transducer and the moving mechanism to form a scrape on the wire by the inner edge of the bonding tool, and raise the tip of the bonding tool by the moving mechanism and close the wire clamper to cut off the wire at a portion of the scrape and form a pin wire extending upward from the bonding position.

In the wire bonding apparatus according to the present invention, the control part may be configured to: incline the wire by moving the tip of the bonding tool obliquely downward by the moving mechanism when pressing the inner edge of the bonding tool against the wire, vibrate the tip of the bonding tool with the wire being inclined to form a scrape on the wire by the inner edge of the bonding tool, and move the tip of the bonding tool obliquely upward to above the bonding position by the moving mechanism to stand the wire to extend vertically upward from the bonding position.

In the wire bonding apparatus according to the present invention, the bonding tool may include a tip surface, a recess, and a through-hole. The recess is recessed from the tip surface toward a root and narrows toward the root. The through-hole is connected to a bottom surface of the recess and extends toward the root, and the wire is inserted through the through-hole. The inner edge may be a corner part at which the bottom surface of the recess and an inner surface of the through-hole are connected.

In the wire bonding apparatus according to the present invention, the bottom surface of the recess of the bonding tool may be inclined so that an outer peripheral side is recessed to a root side. An internal angle of the corner part of the bonding tool may be 90° or less.

In the wire bonding apparatus according to the present invention, the through-hole of the bonding tool may have a tapered shape having a diameter that increases toward a root side. An internal angle of the corner part of the bonding tool may be 90° or less.

In the wire bonding apparatus according to the present invention, the recess of the bonding tool may have an inclined surface which is inclined with respect to a center line of the bonding tool at the tip surface. The control part may be configured to move the tip of the bonding tool obliquely downward by the moving mechanism to incline the wire to an inclination angle of the inclined surface of the recess, when pressing the inner edge of the bonding tool against the wire.

A bonding tool according to the present invention is a bonding tool used in a wire bonding apparatus and includes a tip surface, a recess, and a through-hole. The recess is recessed from the tip surface toward a root and narrows toward the root. The through-hole extends from a bottom surface of the recess toward the root, and a wire is inserted through the through-hole. The bonding tool has a corner part at which the bottom surface of the recess and an inner surface of the through-hole are connected. When the wire inserted through the through-hole extends obliquely from the tip surface, the corner part hits a side surface of the wire.

In the bonding tool according to the present invention, the bottom surface may be inclined so that an outer peripheral side is recessed to a root side. An internal angle of the corner part may be 90° or less.

In the bonding tool according to the present invention, the through-hole may have a tapered shape having a diameter that increases toward a root side. An internal angle of the corner part may be 90° or less.

### Effect of Invention

In the present invention, a pin wire can be formed without pressing a portion of a wire at a location different from a bonding position.

### BRIEF DESCRIPTION OF DRAWINGS

FIG. 1 is an elevational view showing a configuration of a wire bonding apparatus according to an embodiment.

FIG. 2 is a cross-sectional view of a capillary attached to the wire bonding apparatus shown in FIG. 1.

FIG. 3 is a detailed cross-sectional view of part A shown in FIG. 1.

FIG. 4 is a flowchart of an operation of forming a pin wire by the bonding apparatus shown in FIG. 1.

FIG. 5 is an explanatory view showing a state in which a tip of a wire is formed into a free air ball and a center of the capillary is moved to directly above an electrode of a semiconductor chip in a bonding process.

FIG. 6 is an explanatory view showing a state in which the tip of the capillary is lowered to press the free air ball onto the electrode by the tip of the capillary to form a press-bonding ball and bond the wire onto the electrode in the bonding process.

FIG. 7 is an explanatory view showing a state in which the tip of the capillary is raised, and the wire is fed out so that the wire extends vertically upward from the electrode in a wire feeding process.

FIG. 8 is an explanatory view showing a state in which a wire clamper is closed after the wire is fed out as shown in FIG. 7.

FIG. 9 is an explanatory view showing a state in which the tip of the capillary is moved obliquely downward to incline the wire and press an inner edge of the capillary against the wire in a pressing process.

FIG. 10 is a cross-sectional view showing details of part B shown in FIG. 9, and is an explanatory view showing a state in which the capillary is vibrated with a corner part of the capillary being pressed against a side surface of the wire in a scraping process.

FIG. 11 is an explanatory view showing a state in which the tip of the capillary is moved obliquely upward to above the electrode to stand the wire in a wire standing process.

FIG. 12 is an explanatory view showing a state in which the wire clamper is opened and the capillary is raised to extend the wire from the tip of the capillary in a wire cut-off process.

FIG. 13 is an explanatory view showing a state in which the clamper is closed while the tip of the capillary is being raised after the state shown in FIG. 12 to cut off the wire at a portion of a scrape in the wire cut-off process.

FIG. 14 is a detailed cross-sectional view showing another tip shape of the capillary.

FIG. 15 is a detailed cross-sectional view showing another tip shape of the capillary.

FIG. 16 is a detailed cross-sectional view showing another tip shape of the capillary.

FIG. 17 is a flowchart of another operation of forming a pin wire by the bonding apparatus shown in FIG. 1.

FIG. 18 is an explanatory view showing a state in which the tip of the capillary is laterally moved to press the inner edge of the capillary against the wire in the pressing process shown in FIG. 17.

FIG. 19 is a view showing a state in which the tip of the capillary is raised obliquely upward in the cut-off process shown in FIG. 17.

FIG. 20 is an explanatory view showing a state in which the tip of the capillary is moved to a position directly above the electrode after the state shown in FIG. 19 in the cut-off process shown in FIG. 17.

FIG. 21 is an explanatory view showing a state in which the clamper is closed while the tip of the capillary is being raised after the state shown in FIG. 20 to cut off the wire at the portion of the scrape in the cut-off process shown in FIG. 17.

### DESCRIPTION OF EMBODIMENTS

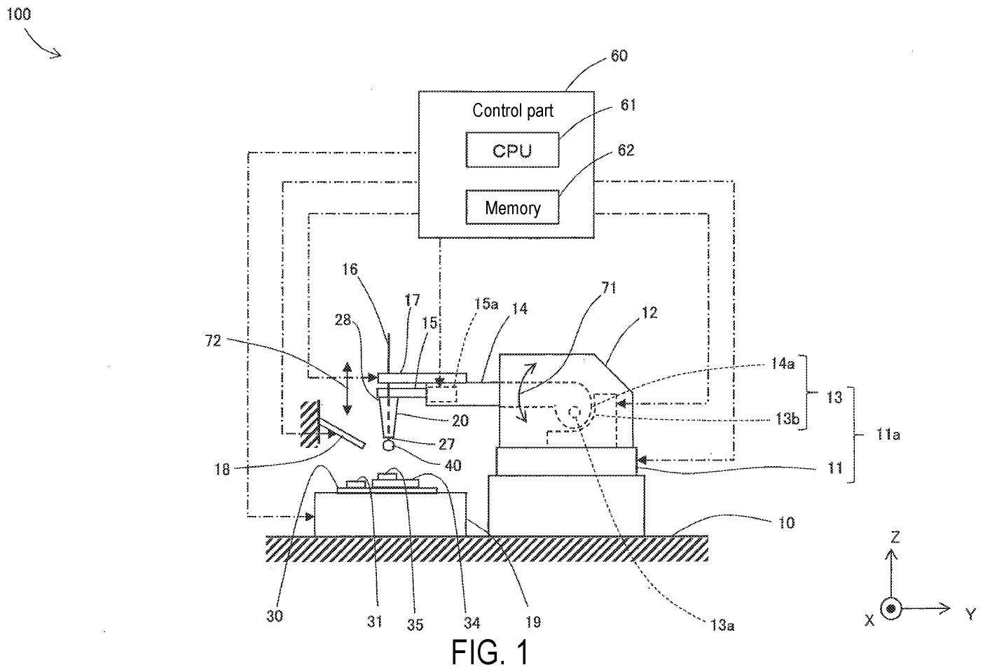

Hereinafter, a wire bonding apparatus 100 according to an embodiment will be described with reference to the drawings. As shown in FIG. 1, the wire bonding apparatus 100 bonds a wire 16 onto, as a bonding position, an electrode 35 of a semiconductor chip 34 or an electrode 31 of a substrate 30 by using a bonding tool. In the following description, the case where a capillary 20 is used as the bonding tool will be described.

As shown in FIG. 1, the wire bonding apparatus 100 includes a base 10, an XY table 11, a bonding head 12, a Z-direction motor 13, a bonding arm 14, an ultrasonic horn 15, an ultrasonic transducer 15a, a capillary 20 as a bonding tool, a wire clamper 17, a discharge electrode 18, a bonding stage 19, and a control part 60. In the following description, the direction in which the bonding arm 14 or the ultrasonic horn 15 extends will be taken as the Y direction, the horizontal direction perpendicular to the Y direction will be taken as the X direction, and the vertical direction will be taken as the Z direction. Further, the ultrasonic horn 15 side will be taken as the front side or the negative side in the Y direction; the bonding head 12 side will be taken as the rear side or the positive side in the Y direction; the paper surface front side in FIG. 1 will be taken as the positive side in the X direction; the other side of the paper surface will be taken as the negative side in the X direction; the upward direction will be taken as the positive side in the Z direction; and the downward direction will be taken as the negative side in the Z direction.

The XY table 11 is mounted on the base 10 to move a device mounted thereon in the XY directions.

The bonding head 12 is mounted on the XY table 11 and is moved in the XY directions by the XY table 11. The Z-direction motor 13 and the bonding arm 14 driven by the Z-direction motor 13 are accommodated in the bonding head 12. The Z-direction motor 13 includes a stator 13b. The bonding arm 14 includes a root part 14a that is opposed to the stator 13b of the Z-direction motor 13 and forms as a rotor rotatably attached around a shaft 13a of the Z-direction motor 13.

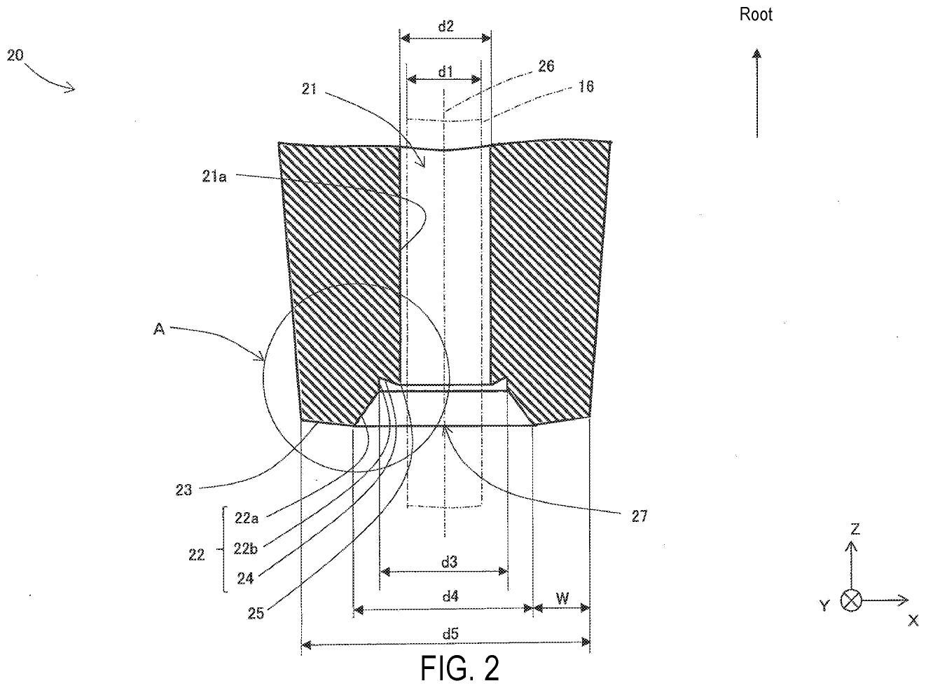

The ultrasonic horn 15 is attached to the front end of the bonding arm 14 on the negative side in the Y direction, and the capillary 20 is attached to the front end of the ultrasonic horn 15. The ultrasonic horn 15 amplifies ultrasonic vibration of the ultrasonic transducer 15a attached to the front end part of the bonding arm 14 to ultrasonically vibrate the capillary 20 attached to the front end. As will be described later with reference to FIG. 2, the capillary 20 is provided with a through-hole 21 penetrating inside in the vertical direction, and the wire 16 is inserted through the through-hole 21. The wire 16 is supplied from a wire supply such as a wire spool (not shown).

Further, the wire clamper 17 is attached to the upper surface of the bonding arm 14 on the front end side. The wire clamper 17 extends to the front end of the ultrasonic horn 15 to which the capillary 20 is attached, and opens and closes in the X direction to grip and release the wire 16.

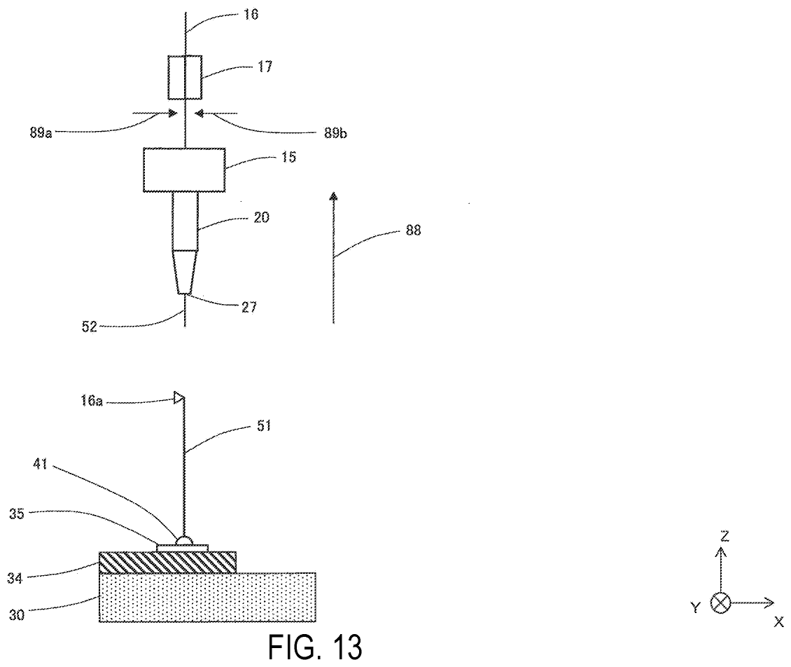

The discharge electrode 18 is provided on the upper side of the bonding stage 19. The discharge electrode 18 may be attached to a frame (not shown) provided on the base 10. The discharge electrode 18 performs discharge with respect to a wire tail 52 (see FIG. 13) that is inserted into the capillary 20 and extends from a tip 27 of the capillary 20, and melts the wire tail 52 to form a free air ball 40.

The bonding stage 19 fixes, by suction, the substrate 30 mounted with the semiconductor chip 34 on the upper surface, and heats the substrate 30 and the semiconductor chip 34 by a heater (not shown).

When the root part 14a of the bonding arm 14 forming the rotor rotates around the shaft 13a as indicated by an arrow 71 in FIG. 1 by the electromagnetic force of the stator 13b of the Z-direction motor 13, the tip 27 of the capillary 20 attached to the front end of the ultrasonic horn 15 moves in the Z direction as indicated by an arrow 72. Further, the bonding head 12 is moved in the XY directions by the XY table 11. Thus, the tip 27 of the capillary 20 is moved in the XYZ directions by the XY table 11 and the Z-direction motor 13. Further, the wire clamper 17 moves in the XYZ directions together with the bonding arm 14 and the capillary 20. Thus, the XY table 11 and the Z-direction motor 13 form a moving mechanism 11a which moves the tip 27 of the capillary 20 and the wire clamper 17 in the XYZ directions.

The XY table 11, the Z-direction motor 13, the ultrasonic transducer 15a, the wire clamper 17, the discharge electrode 18, and the bonding stage 19 are connected to the control part 60 and operate based on the commands from the control part 60. The control part 60 adjusts the position of the tip 27 of the capillary 20 in the XYZ directions by the moving mechanism 11a composed of the XY table 11 and the Z-direction motor 13, and performs opening and closing of the wire clamper 17, driving of the ultrasonic transducer 15a, driving of the discharge electrode 18, and heating control of the bonding stage 19.

The control part 60 is a computer including a CPU 61, which is a processor that internally processes information, and a memory 62 that stores operation programs, operation data, etc.

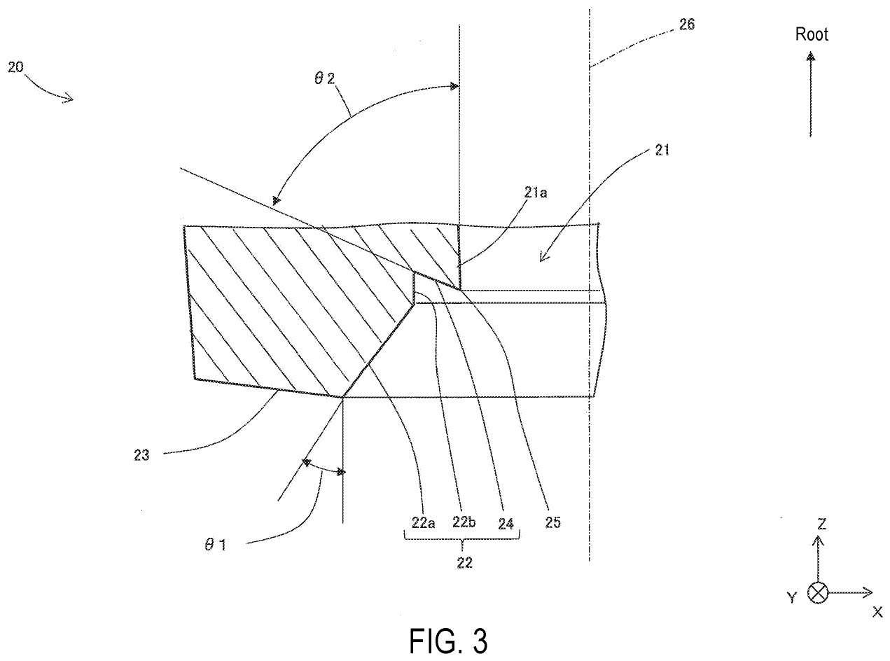

Next, the configuration of the capillary 20 will be described with reference to FIG. 2 and FIG. 3. In the following description, the X direction, the Y direction, and the Z direction indicate the directions when the capillary 20 has been attached to the ultrasonic horn 15. As shown in FIG. 1, a root 28 of the capillary 20 is attached to the ultrasonic horn 15, and the tip 27 bonds the wire 16 to the electrodes 31 and 35.

As shown in FIG. 2, the capillary 20 is an elongated frusto-conical member having a diameter that gradually narrows toward the tip 27. The outer diameter of the tip 27 is d5. A tip surface 23 having a width W that presses the free air ball 40 shown in FIG. 1 is formed on the outer periphery of the tip 27. The tip surface 23 may be a flat horizontal surface, or may be a slightly inclined surface that advances upward toward the outer side. A recess 22 that is recessed from the tip surface 23 toward the root 28 and narrows toward the root 28 is formed at the center of the tip 27. The recess 22 is composed of an inclined surface 22a, a cylindrical surface 22b having a constant diameter, and a bottom surface 24. A through-hole 21 having a diameter d2 that penetrates in the longitudinal direction and through which the wire 16 having a diameter d1 passes is formed at the center of the bottom surface 24.

As shown in FIG. 3, the inclined surface 22a is a conical surface having a diameter that decreases from the tip surface 23 toward the root 28, the diameter at the tip surface 23 is d4, and the diameter on the root 28 side is d3, where d4>d3. The root 28 side of the inclined surface 22a is connected to the cylindrical surface 22b having the diameter d3. Further, the inclined surface 22a is inclined by an angle θ1 with respect to a center line 26 of the capillary 20 at the tip surface 23.

The bottom surface 24 is inclined so that the outer peripheral side is recessed toward the root 28 side, and an internal angle θ2 of a corner part 25 at which the bottom surface 24 and an inner surface 21a of the through-hole 21 are connected is an acute angle of 90° or less.

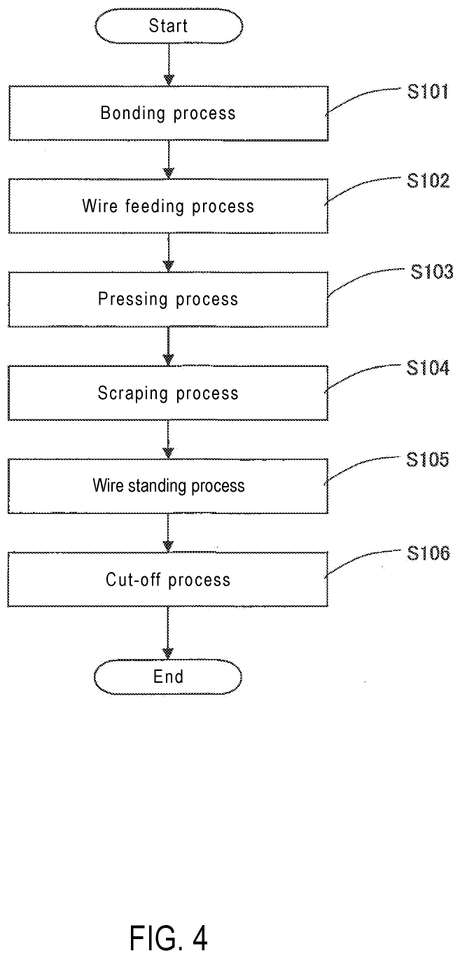

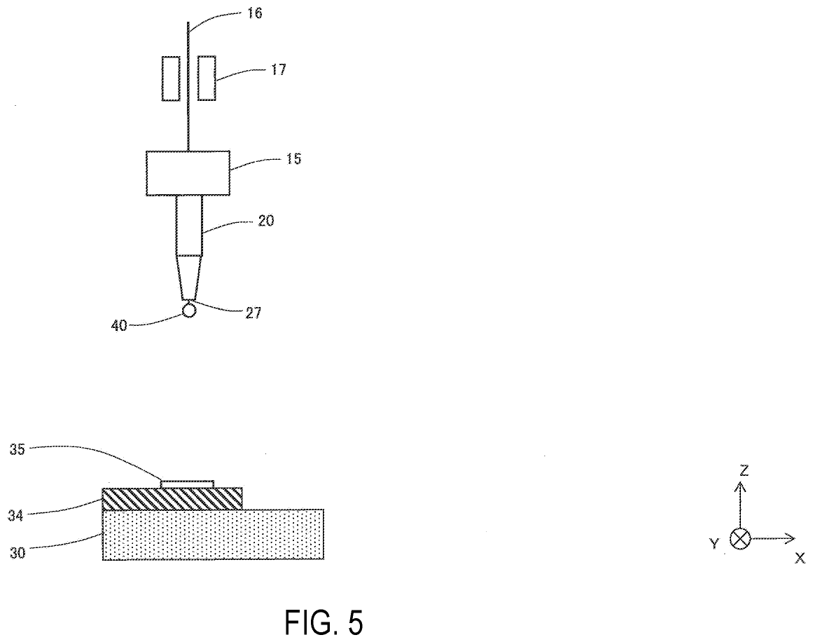

Next, an operation of forming a pin wire 51 shown in FIG. 13 using the wire bonding apparatus 100 will be described with reference to FIG. 4 to FIG. 13. In the following description, the case of forming a pin wire 51 on the electrode 35 of the semiconductor chip 34 mounted on the substrate 30 will be described. FIG. 5 to FIG. 9 and FIG. 10 to FIG. 13 are views of the substrate 30, the semiconductor chip 34, the capillary 20, the ultrasonic horn 15, the wire clamper 17, and the wire 16 as viewed from the negative side in the Y direction.

As shown in step S101 of FIG. 4, the CPU 61, which is the processor of the control part 60, first executes a bonding process.

The CPU 61 of the control part 60 releases the wire clamper 17 and controls driving of the XY table 11 and the Z-direction motor 13 shown in FIG. 1 to move the tip 27 of the capillary 20 to the vicinity of the discharge electrode 18. Then, the CPU 61 generates discharge between the discharge electrode 18 and the wire tail 52 (see FIG. 13) extending from the tip 27 of the capillary 20, and, as shown in FIG. 5, forms the wire tail 52 extending from the tip 27 of the capillary 20 into a free air ball 40. Then, the CPU 61 controls driving of the XY table 11 and the Z-direction motor 13 to move the tip 27 of the capillary 20 to directly above the electrode 35 of the semiconductor chip 34, which is the bonding position.

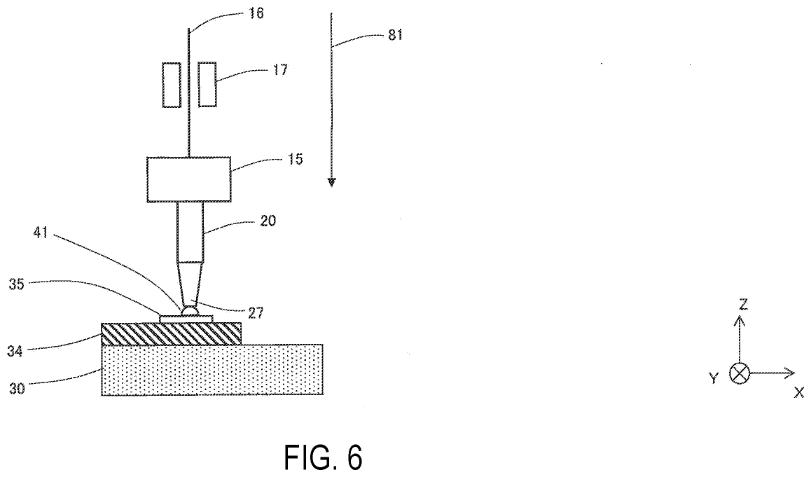

Then, the CPU 61 lowers the tip 27 of the capillary 20 toward the electrode 35 of the semiconductor chip 34 as indicated by an arrow 81 shown in FIG. 6, and bonds the free air ball 40 onto the electrode 35 by the tip surface 23 of the capillary 20 shown in FIG. 3 to form a press-bonding ball 41 to join the wire 16 to the electrode 35. After bonding the wire 16 to the electrode 35, the CPU 61 ends the bonding process.

Next, the CPU 61 of the control part 60 executes a wire feeding process as shown in step S102 of FIG. 4.

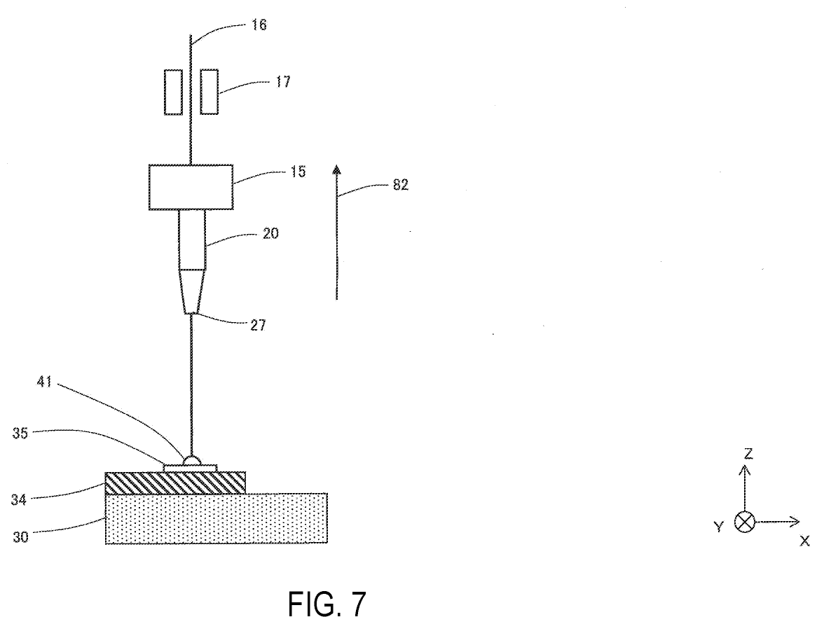

As shown in FIG. 7, the CPU 61 controls driving of the XY table 11 and the Z-direction motor 13 shown in FIG. 1 with the wire clamper 17 being opened to raise the tip 27 of the capillary 20 as indicated by an arrow 82 shown in FIG. 7 to feed the wire 16 from the tip 27 of the capillary 20. The wire 16 is fed from the tip 27 of the capillary 20 to extend vertically upward from the electrode 35 which is the bonding position. Then, when the length of the fed wire 16 reaches the height of the pin wire 51 to be formed, the CPU 61 ends the feeding process.

Next, the CPU 61 of the control part 60 executes a pressing process as shown in step S103 of FIG. 4.

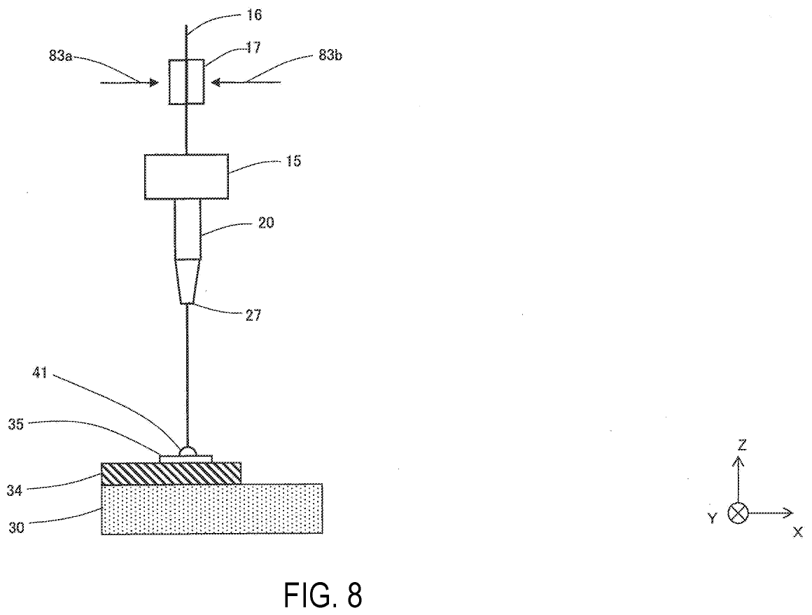

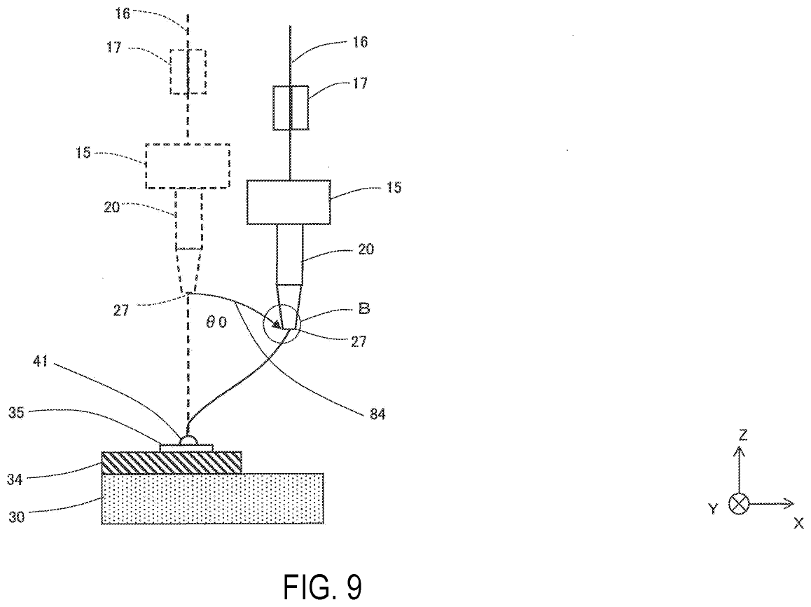

The CPU 61 closes the wire clamper 17 as indicated by arrows 83a and 83b shown in FIG. 8. Then, the CPU 61 controls driving of the XY table 11 and the Z-direction motor 13 shown in FIG. 1 to move the tip 27 of the capillary 20 by an angle θ0 in an arc shape toward the positive side in the X direction as indicated by an arrow 84 in FIG. 9, and positions the tip 27 of the capillary 20 obliquely downward on the positive side in the X direction from the position shown in FIG. 8. Herein, the angle θ0 is the same angle as the inclination angle θ1 of the inclined surface 22a of the capillary 20 with respect to the center line 26 of the capillary 20 at the tip surface 23. A broken line in FIG. 9 indicates the state before the pressing process is started, and a solid line indicates the state when the pressing process is ended.

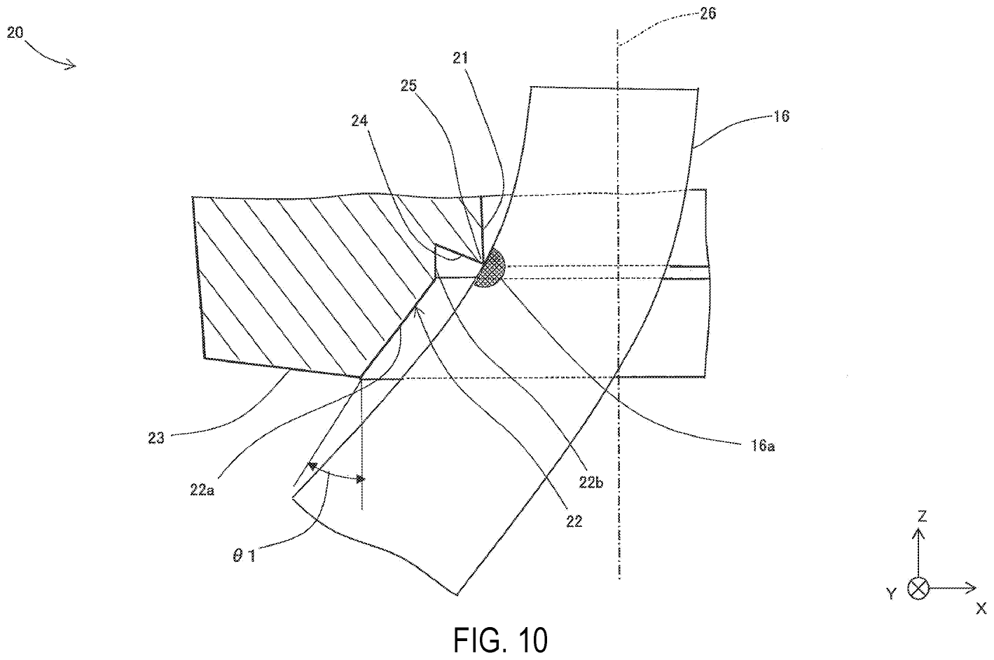

Accordingly, as shown in FIG. 10, the wire 16 bonded onto the electrode 35 is bent to the positive side in the X direction due to the corner part 25 which is an inner edge of the capillary 20, and is inclined from the electrode 35 toward the tip 27 of the capillary 20. At this time, the side surface of the wire 16 is pressed against the corner part 25 due to the reaction force of the bending of the wire 16. Since the tip 27 of the capillary 20 moves in an arc shape by the angle 00 which is the same angle as the inclination angle θ1 of the inclined surface 22a with respect to the center line 26 of the capillary 20 at the tip surface 23, in the states shown in FIGS. 9 and 10, the inner peripheral edge of the tip surface 23 is not in contact with the side surface of the wire 16.

After moving the tip 27 of the capillary 20 by the angle θ0 in an arc shape toward the positive side in the X direction, the CPU 61 ends the pressing process.

Next, the CPU 61 of the control part 60 executes a scraping process shown in step S104 of FIG. 4.

The CPU 61 of the control part 60 drives the ultrasonic transducer 15a shown in FIG. 1 to ultrasonically vibrate the ultrasonic horn 15 in the Y direction. Accordingly, the tip 27 of the capillary 20 is ultrasonically vibrated in the Y direction. The frequency of the ultrasonic vibration may be freely selected, but may be in the range of 120 kHz to 150 kHz, for example.

Thus, when the tip 27 of the capillary 20 is ultrasonically vibrated in the Y direction, a portion of the side surface of the wire 16 that is pressed against the corner part 25 of the capillary 20 is scraped by the ultrasonic vibration of the corner part 25 in the Y direction. Further, since the corner part 25 has an acute angle, the tip of the corner part 25 digs into the wire 16 while scraping the side surface of the wire 16 by ultrasonic vibration, and as shown by hatching in FIG. 10, a scrape 16a is formed on the side surface of the wire 16.

After driving the ultrasonic transducer 15a for a predetermined time, the CPU 61 ends the scraping process.

Next, the CPU 61 of the control part 60 executes a wire standing process shown in step S105 of FIG. 4.

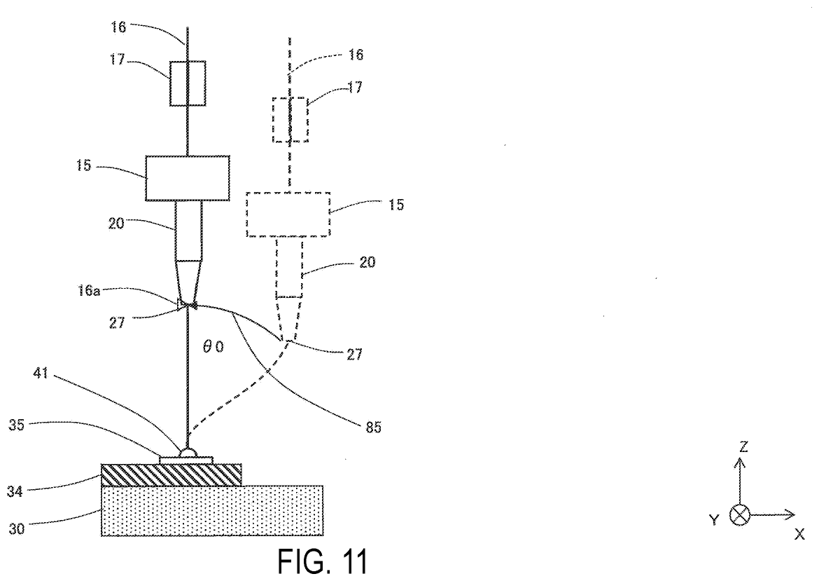

The CPU 61 controls driving of the XY table 11 and the Z-direction motor 13 shown in FIG. 1 to move the tip 27 of the capillary 20 by the angle θ0 in an arc shape toward the negative side in the X direction as indicated by an arrow 85 shown in FIG. 11 and move the position of the tip 27 of the capillary 20 from the position shown in FIG. 9 to above the electrode 35 of the semiconductor chip 34. Accordingly, the wire 16 stands up to extend vertically upward from the electrode 35. Herein, a broken line in FIG. 11 indicates the state before the wire standing process is started, and a solid line indicates the state when the wire standing process is ended. Further, a triangular mark in FIG. 11 indicates the position of the scrape 16a formed on the wire 16.

Next, the CPU 61 of the control part 60 executes a cut-off process shown in step S106 of FIG. 4.

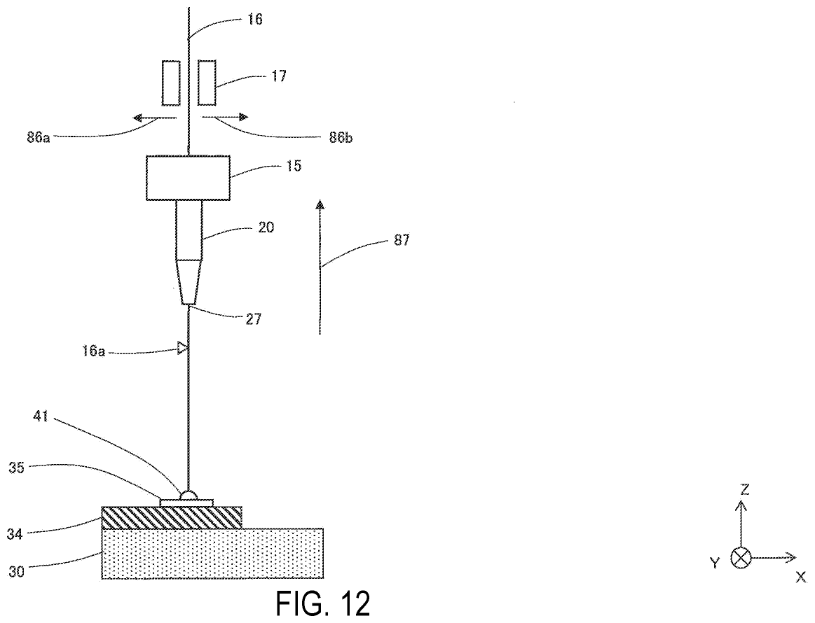

The CPU 61 opens the wire clamper 17 as indicated by arrows 86a and 86b shown in FIG. 12 and controls driving of the XY table 11 and the Z-direction motor 13 shown in FIG. 1 as indicated by an arrow 87 in FIG. 12 to raise the tip 27 of the capillary 20. Then, after extending the wire 16 of a predetermined length from the tip 27 of the capillary 20, the wire clamper 17 is closed as indicated by arrows 89a and 89b shown in FIG. 13 while the tip 27 of the capillary 20 is being raised as indicated by an arrow 88 shown in FIG. 13. Then, due to the raise of the capillary 20 and the wire clamper 17, the wire 16 is cut off at the portion of the scrape 16a. When the wire 16 is cut off, a pin wire 51 extending vertically upward from the electrode 35 is formed. A wire tail 52 which will be formed into a free air ball 40 in a next bonding process extends from the lower end of the capillary 20. After cutting off the wire 16, the CPU 61 ends the cut-off process.

In the pin wire forming method described above, since the tip 27 of the capillary 20 is ultrasonically vibrated with the wire 16 being inclined and the corner part 25 of the capillary 20 being pressed against the side surface of the wire 16, the corner part 25 digs into the wire 16 while scraping the side surface of the wire 16, and a deep scrape 16a can be formed on the side surface of the wire 16. Thus, in the cut-off process, the wire 16 can be reliably cut off at the portion of the scrape 16a to form a pin wire 51.

Further, in the pin wire forming method, since a deep scrape 16a can be formed on the side surface of the wire 16 with the wire 16 being inclined, the pin wire 51 can be formed without pressing a portion of the wire 16 at a location different from the bonding position as in the related art described in Patent Document 2. Accordingly, the pin wire 51 can be easily formed even when there is no space for pressing the wire 16. Further, the pin wire 51 can be formed without interfering with an adjacent pin wire 51 even when the pitch of the pin wires 51 is narrow.

In the wire forming method described above, although it has been described that in the scraping process, the tip 27 of the capillary 20 is ultrasonically vibrated by the ultrasonic transducer 15a in the Y direction to form a scrape 16a on the side surface of the wire 16, the embodiment is not limited thereto.

For example, the scrape 16a may also be formed on the side surface of the wire 16 by the corner part 25 of the capillary 20 by controlling driving of the XY table 11 and the Z-direction motor 13 shown in FIG. 1 to vibrate the tip 27 of the capillary 20 in the X direction, the Y direction, and the Z direction. The frequency at this time may be freely selected, but may be, for example, about 200 Hz to 800 Hz. Further, instead of vibrating in the three directions, i.e., the XYZ directions, it is also possible to vibrate in one or more directions among the X direction, the Y direction, and the Z direction.

Further, the tip 27 of the capillary 20 may be ultrasonically vibrated in two directions, i.e., the X direction and the Y direction, by using a composite ultrasonic horn for vibrating the tip 27 of the capillary 20 in multiple directions as described in Patent Document 1. The frequency of the ultrasonic vibration in this case may be freely selected, but may be in the range of 60 kHz to 150 kHz, for example.

Further, in the pin wire forming method described above, although it has been described that in the pressing process, the tip 27 of the capillary 20 is moved in an arc shape by an angle θ0 that is the same angle as the inclination angle θ1 of the inclined surface 22a with respect to the center line 26 of the capillary 20 at the tip surface 23, the embodiment is not limited thereto. As long as the side surface of the wire 16 does not touch the inner peripheral edge of the tip surface 23, the angle θ0 may be smaller than or slightly larger than the inclination angle θ1.

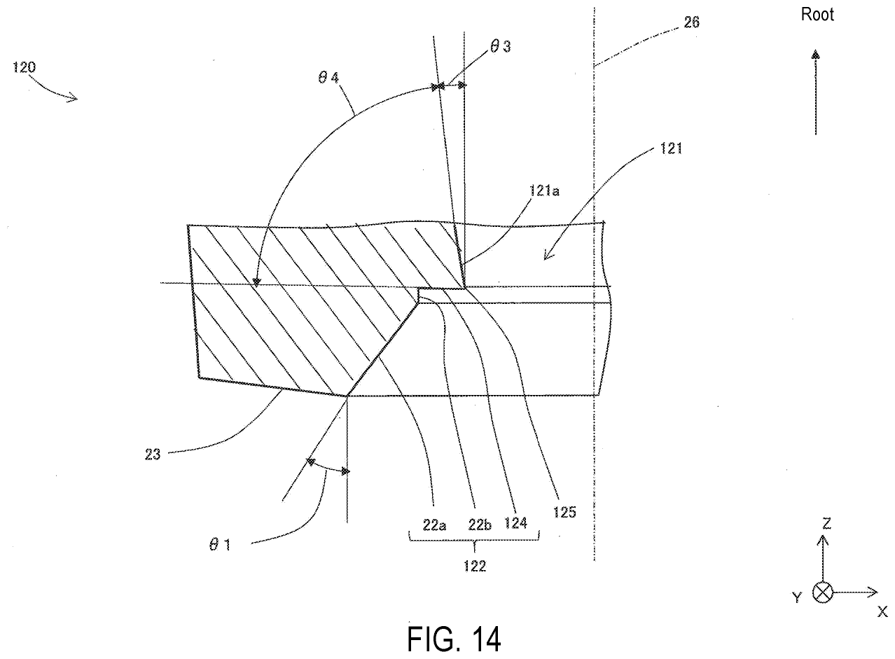

Next, referring to FIG. 14 to FIG. 16, capillaries 120, 220, and 320 of other embodiments which are attached to the wire bonding apparatus 100 to form the pin wire 51 will be described. The same parts as those of the capillary 20 described above with reference to FIG. 2 and FIG. 3 will be labeled with the same reference signs, and descriptions thereof will be omitted.

In the capillary 120 shown in FIG. 14, by forming a bottom surface 124 of a recess 122 as a planar surface perpendicular to the center line 26 and forming a through-hole 121 into a tapered shape having a diameter that increases toward the root 28 side, the internal angle of a corner part 125 is formed as an acute angle of 90° or less. An inner surface 121a of the through-hole 121 is inclined to the outer diameter side by an angle θ3, and the internal angle of the corner part 125 is an angle θ4 smaller than 90°. Similarly, in the case of using the capillary 120, the pin wire 51 may be formed by executing the pin wire forming method described above.

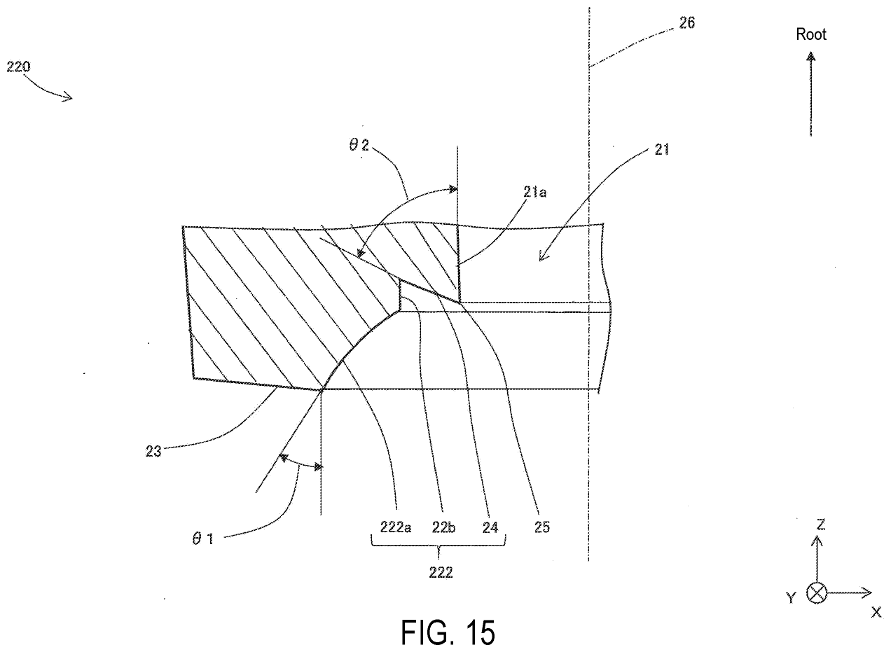

In the capillary 220 shown in FIG. 15, an inclined surface 222a of a recess 222 is formed as a curved surface. Similar to the description with reference to FIG. 2 and FIG. 3, the inclination angle of the inclined surface 222a with respect to the center line 26 of the capillary 20 at the tip surface 23 is θ1. Similarly, in the case of using the capillary 220, the pin wire 51 may be formed by executing the pin wire forming method described above.

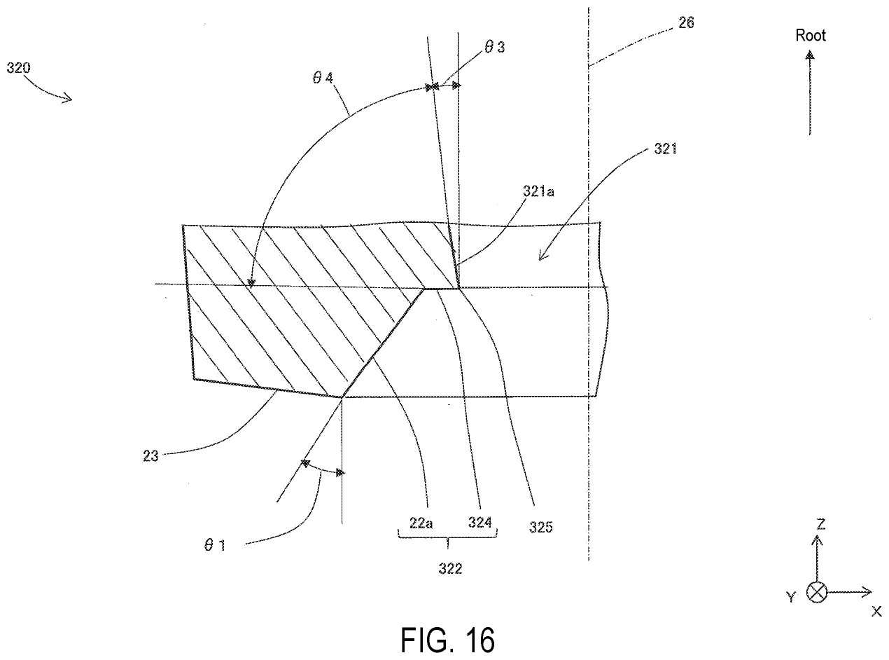

In the capillary 320 shown in FIG. 16, a recess 322 is composed of the inclined surface 22a and a planar bottom surface 324 perpendicular to the center line 26; without the cylindrical surface 22b, an inner surface 321a of a through-hole 321 is inclined to the outer diameter side by an angle θ3 to form the internal angle of a corner part 325 as an acute angle θ4 smaller than 90°. Similarly, in the case of using the capillary 320, the pin wire 51 may be formed by executing the pin wire forming method described above.

As described above, the wire bonding apparatus 100 of the embodiment can execute the wire bonding method described above to form the pin wire 51 without pressing a portion of the wire 16 at a location different from the bonding position. Accordingly, the pin wire 51 can be easily formed even when there is no space for pressing the wire 16. Further, the pin wire 51 can be formed without interfering with an adjacent pin wire 51 even when the pitch of the pin wires 51 is narrow.

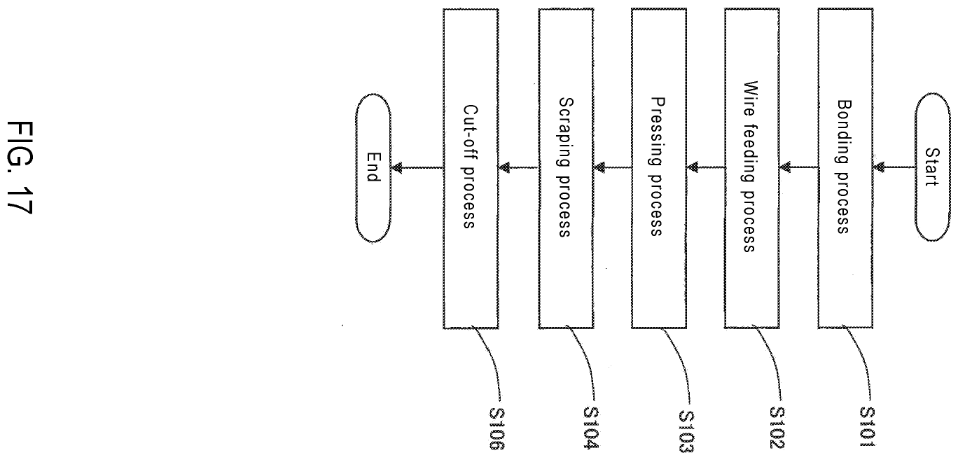

Next, another operation for forming the pin wire 51 shown in FIG. 13 by using the wire bonding apparatus 100 will be described with reference to FIG. 17 to FIG. 21. The same operations as those described above with reference to FIG. 4 to FIG. 13 will be labeled with the same reference signs, and descriptions thereof will be omitted. As shown in FIG. 17, in the another operation, in the pressing process of step S103, the tip 27 of the capillary 20 is laterally moved and the tip 27 of the capillary 20 is vibrated with the corner part 25 of the capillary 20 being pressed against the side surface of the wire to form a scrape 16a on the side surface of the wire. Afterwards, after moving the tip 27 of the capillary 20 to a position directly above the electrode 35 while raising the tip 27, the wire clamper 17 is closed while the tip 27 of the capillary 20 is raised to cut off the wire 16 at the portion of the scrape 16a to form a pin wire 51. Thus, the another operation does not include the wire standing process of step S105 of FIG. 4, which will be described below.

After executing the bonding process and the wire feeding process as shown in step S101 to step 102 in FIG. 17, the CPU 61 of the control part 60 proceeds to step S103 in FIG. 17 to execute the pressing process.

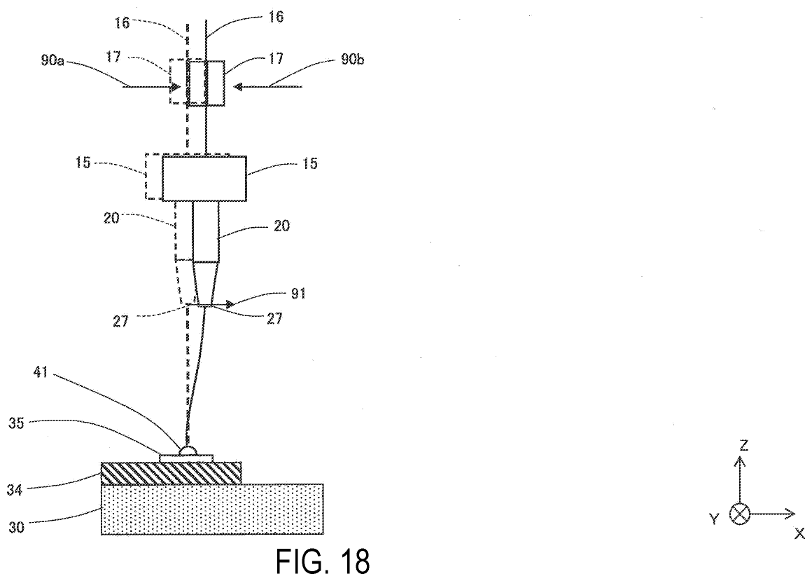

The CPU 61 closes the wire clamper 17 as indicated by arrows 90a and 90b, similar to the description above with reference to FIG. 8. Then, the CPU 61 controls driving of the XY table 11 shown in FIG. 1 to move the tip 27 of the capillary 20 toward the positive side in the X direction as indicated by an arrow 91 shown in FIG. 18. Accordingly, the corner part 25 of the capillary 20 is pressed against the side surface of the wire 16. A broken line in FIG. 18 indicates the state before the pressing process is started, and a solid line indicates the state when the pressing process is ended.

After moving the tip 27 of the capillary 20 in the lateral direction, the CPU 61 ends the pressing process and proceeds to step S104 in FIG. 17 to execute the scraping process. In the state shown in FIG. 18, the CPU 61 drives the ultrasonic transducer 15a shown in FIG. 1 to ultrasonically vibrate the ultrasonic horn 15 in the Y direction to form a scrape 16a on the side surface of the wire 16. After driving the ultrasonic transducer 15a for a predetermined time, the CPU 61 ends the scraping process.

After ending the scraping process, the CPU 61 proceeds to step S106 in FIG. 17 to execute the cut-off process.

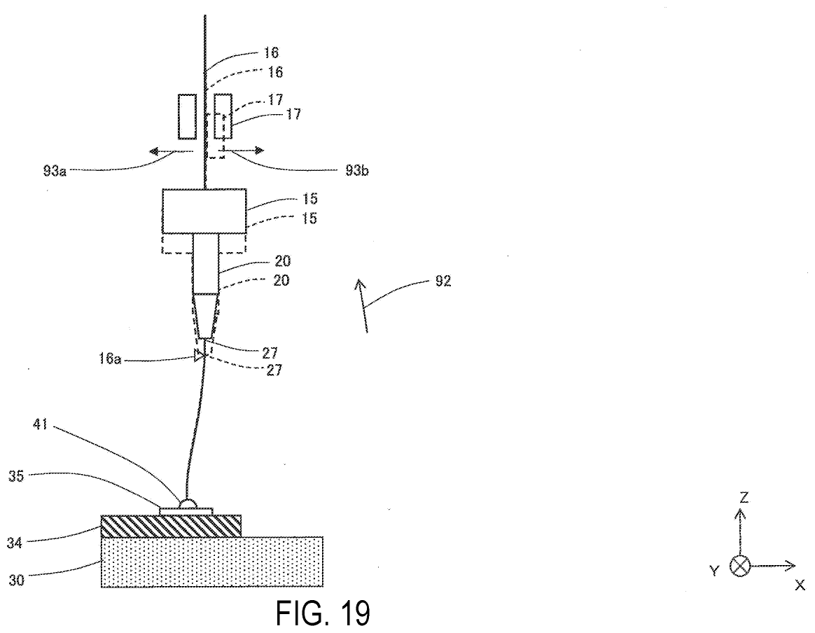

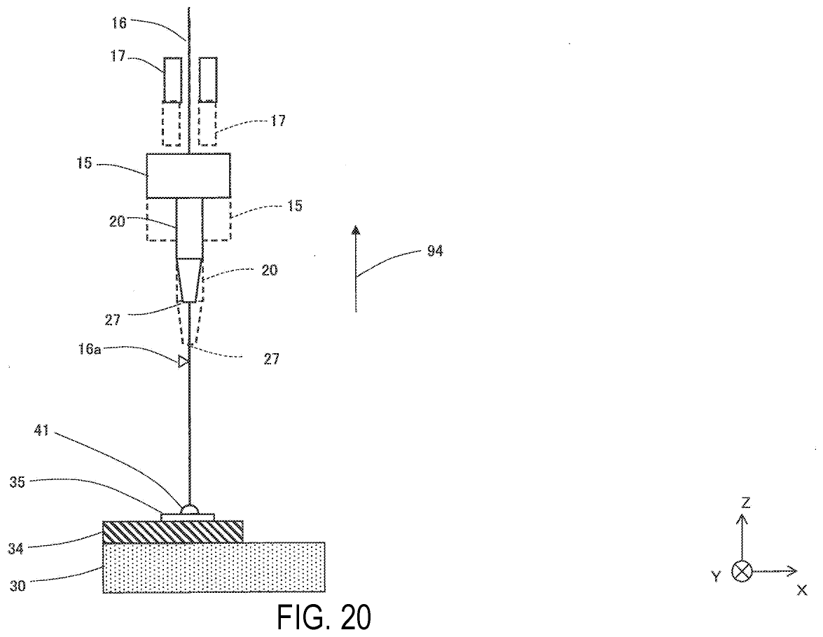

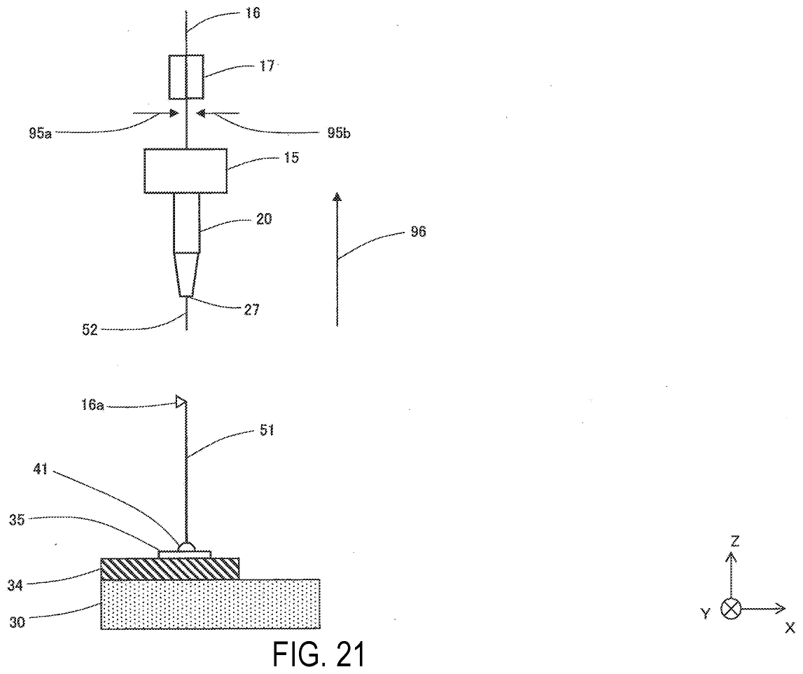

The CPU 61 opens the wire clamper 17 as indicated by arrows 93a and 93b in FIG. 19, controls driving of the XY table 11 and the Z-direction motor 13 shown in FIG. 1 as indicated by an arrow 92 shown in FIG. 19 to raise the tip 27 of the capillary 20 and move the tip 27 to the negative side in the X-direction. Then, after the tip 27 of the capillary 20 is positioned directly above the electrode 35, the CPU 61 stops the movement of the tip 27 of the capillary 20 to the negative side in the X direction and raises the tip 27 of the capillary 20 as indicated by an arrow 94 shown in FIG. 20. Then, after extending the wire 16 of a predetermined length from the tip 27 of the capillary 20, the CPU 61 closes the wire clamper 17 as indicated by arrows 95a and 95b shown in FIG. 21 while the tip 27 of the capillary 20 is being raised as indicated by an arrow 96 shown in FIG. 21. Accordingly, the wire 16 is cut off at the portion of the scrape 16a to form a pin wire 51 extending vertically upward from the electrode 35. Further, a wire tail 52 which will be formed into a free air ball 40 in a next bonding process extends from the lower end of the capillary 20. After cutting off the wire 16, the CPU 61 ends the cut-off process.

In the operation described above, since a scrape 16a is formed on the wire 16 with the tip 27 of the capillary 20 having been moved laterally, and the cut-off process is performed without performing the wire standing process, the pin wire 51 can be formed in a shorter time than the operation described above with reference to FIG. 4 to FIG. 13.

### REFERENCE SIGNS LIST

10 base; 11 XY table; 11a moving mechanism; 12 bonding head; 13 Z-direction motor; 13a shaft; 13b stator; 14 bonding arm; 14a root part; 15 ultrasonic horn; 15a ultrasonic transducer; 16 wire; 16a scrape; 17 wire clamper; 18 discharge electrode; 19 bonding stage; 20, 120, 220, 320 capillary; 21, 121, 321 through-hole; 21a, 121a, 321a inner surface; 22, 122, 222, 322 recess; 22a, 222a inclined surface; 22b cylindrical surface; 23 tip surface; 24, 124, 324 bottom surface; 25, 125, 325 corner part; 26 center line; 27 tip; 28 root; 30 substrate; 31, 35 electrode; 34 semiconductor chip; 40 free air ball; 51 pin wire; 52 wire tail; 60 control part; 61 CPU; 62 memory; 100 wire bonding apparatus

1. A pin wire forming method comprising:
a bonding process of bonding a wire to a bonding position by a bonding tool;
a wire feeding process of raising the bonding tool and feeding the wire from a tip of the bonding tool so that the wire extends upward from the bonding position;
a pressing process of moving the bonding tool to press an inner edge of the bonding tool against the wire;
a scraping process of vibrating the tip of the bonding tool to form a scrape on the wire by the inner edge of the bonding tool; and
a cut-off process of raising the bonding tool and closing a wire clamper to cut off the wire at a portion of the scrape and form a pin wire extending upward from the bonding position.

2. The pin wire forming method according to claim 1, wherein
the pressing process inclines the wire by moving the tip of the bonding tool obliquely downward to press the inner edge of the bonding tool against a side surface of the wire,
the scraping process vibrates the tip of the bonding tool with the wire being inclined to form the scrape on the wire by the inner edge of the bonding tool, and
the pin wire forming method comprises a wire standing process of moving the tip of the bonding tool obliquely upward to above the bonding position to stand the wire to extend vertically upward from the bonding position.

3. The pin wire forming method according to claim 1, wherein
the scraping process vibrates the tip of the bonding tool in any one or more directions among an X direction, a Y direction, and a Z direction by ultrasonically vibrating the bonding tool.

4. The pin wire forming method according to claim 1, wherein
the scraping process vibrates the tip of the bonding tool in any one or more directions among an X direction, a Y direction, and a Z direction by a moving mechanism which moves the tip of the bonding tool in the X direction, the Y direction, and the Z direction.

5. The pin wire forming method according to claim 4, wherein
the moving mechanism is composed of a Z-direction motor that drives a bonding arm to which the bonding tool is attached at a front end to move the tip of the bonding tool in the Z direction, and an XY table which moves a bonding head attached with the bonding arm in XY directions.

6. The pin wire forming method according to claim 1, wherein the bonding tool comprises:
a tip surface;
a recess which is recessed from the tip surface toward a root and narrows toward the root; and
a through-hole which is connected to a bottom surface of the recess and extends toward the root and through which the wire is inserted, and
the inner edge is a corner part at which the bottom surface of the recess and an inner surface of the through-hole are connected.

7. The pin wire forming method according to claim 6, wherein
the bottom surface of the recess of the bonding tool is inclined so that an outer peripheral side is recessed to a root side, and
an internal angle of the corner part of the bonding tool is 90° or less.

8. The pin wire forming method according to claim 6, wherein
the through-hole of the bonding tool has a tapered shape having a diameter that increases toward a root side, and
an internal angle of the corner part of the bonding tool is 90° or less.

9. The pin wire forming method according to claim 6, wherein
the recess of the bonding tool has an inclined surface which is inclined with respect to a center line of the bonding tool at the tip surface, and
the pressing process inclines the wire to an inclination angle of the inclined surface of the recess by moving the tip of the bonding tool obliquely downward to press the inner edge of the bonding tool against a side surface of the wire.

10. The pin wire forming method according to claim 8, wherein
the recess of the bonding tool has an inclined surface which is inclined with respect to a center line of the bonding tool at the tip surface, and
the pressing process inclines the wire to an inclination angle of the inclined surface of the recess by moving the tip of the bonding tool obliquely downward to press the inner edge of the bonding tool against a side surface of the wire.

11. A wire bonding apparatus which bonds a wire to a bonding position, the wire bonding apparatus comprising:
a bonding tool;
an ultrasonic transducer which ultrasonically vibrates the bonding tool;
a moving mechanism which moves the bonding tool;
a wire clamper which grips the wire; and
a control part which adjusts operations of the ultrasonic transducer, the moving mechanism, and the wire clamper,
the control part being configured to:
lower a tip of the bonding tool to the bonding position by the moving mechanism to bond the wire to the bonding position by the bonding tool,
raise the bonding tool by the moving mechanism to feed the wire from the tip so that the wire extends upward from the bonding position,
move the bonding tool by the moving mechanism to press an inner edge of the bonding tool against the wire,
vibrate the tip of the bonding tool by one or both of the ultrasonic transducer and the moving mechanism to form a scrape on the wire by the inner edge of the bonding tool, and
raise the tip of the bonding tool by the moving mechanism and close the wire clamper to cut off the wire at a portion of the scrape and form a pin wire extending upward from the bonding position.

12. The wire bonding apparatus according to claim 11, wherein the control part is configured to:
incline the wire by moving the tip of the bonding tool obliquely downward by the moving mechanism when pressing the inner edge of the bonding tool against the wire,
vibrate the tip of the bonding tool with the wire being inclined to form the scrape on the wire by the inner edge of the bonding tool, and
move the tip of the bonding tool obliquely upward to above the bonding position by the moving mechanism to stand the wire to extend vertically upward from the bonding position.

13. The wire bonding apparatus according to claim 11, wherein the bonding tool comprises:
a tip surface;
a recess which is recessed from the tip surface toward a root and narrows toward the root; and
a through-hole which is connected to a bottom surface of the recess and extends toward the root and through which the wire is inserted, and
the inner edge is a corner part at which the bottom surface of the recess and an inner surface of the through-hole are connected.

14. The wire bonding apparatus according to claim 13, wherein
the bottom surface of the recess of the bonding tool is inclined so that an outer peripheral side is recessed to a root side, and
an internal angle of the corner part of the bonding tool is 90° or less.

15. The wire bonding apparatus according to claim 13, wherein
the through-hole of the bonding tool has a tapered shape having a diameter that increases toward a root side, and
an internal angle of the corner part of the bonding tool is 90° or less.

16. The wire bonding apparatus according to claim 13, wherein
the recess of the bonding tool has an inclined surface which is inclined with respect to a center line of the bonding tool at the tip surface,
the control part is configured to move the tip of the bonding tool obliquely downward by the moving mechanism to incline the wire to an inclination angle of the inclined surface of the recess, when pressing the inner edge of the bonding tool against the wire.

17. The wire bonding apparatus according to claim 15, wherein
the recess of the bonding tool has an inclined surface which is inclined with respect to a center line of the bonding tool at the tip surface, and
the control part is configured to move the tip of the bonding tool obliquely downward by the moving mechanism to incline the wire to an inclination angle of the inclined surface of the recess, when pressing the inner edge of the bonding tool against the wire.

18. A bonding tool used in a wire bonding apparatus, the bonding tool comprising:
a tip surface;
a recess which is recessed from the tip surface toward a root and narrows toward the root; and
a through-hole which extends from a bottom surface of the recess toward the root and through which a wire is inserted, wherein
the recess comprises a conical surface having a diameter that decreases from the tip surface toward the root, and a cylindrical surface that is connected to a root side end of the conical surface and extends toward the root.
the bottom surface is an annular surface connected to a root side end of the cylindrical surface.
the bonding tool has a corner part at which an inner peripheral end of the bottom surface of the recess and an inner surface of the through-hole are connected,
the bottom surface is inclined so that an outer peripheral side is recessed to a root side, and
an internal angle of the corner part is 90° or less, and
when the wire inserted through the through-hole extends obliquely from the tip surface, the corner part hits a side surface of the wire.

19. (canceled)

20. The bonding tool according to claim 18, wherein
the through-hole has a tapered shape having a diameter that increases toward a root side, and
an internal angle of the corner part is 90° or less.
